(19) United States
(12) Patent Application Publication
(10) Pub. No.: US 2008/0032502 A1
(43) Pub. Date: Feb. 7, 2008

(54) SAFETY FEATURES FOR SEMICONDUCTOR PROCESSING APPARATUS USING PYROPHORIC PRECURSOR

(75) Inventors: Charles A. Baskin, Austin, TX (US); Timothy Provencher, Gilbert, AZ (US); Mike Manasco, Tempe, AZ (US); Dae-Youn Kim, Daedog-gu (KR)

Correspondence Address: KNOBBE, MARTENS, OLSEN & BEAR LLP, 2040 MAIN STREET, FOURTEENTH FLOOR, IRVINE, CA, 92614, US

(73) Assignee: ASM AMERICA, INC., Phoenix, AZ (US)

(21) Appl. No.: 11/681,055

(22) Filed: Mar. 1, 2007

Related U.S. Application Data
(60) Provisional application No. 60/835,140, filed on Aug. 1, 2006.

(51) Int. Cl. H01L 21/44; C23C 16/00

(52) U.S. Cl. 438/680; 118/719

(57) ABSTRACT

A semiconductor processing apparatus comprises a pyrophoric source vessel within an enclosure, the vessel containing a pyrophoric material. An air intake labyrinth extends away from the enclosure and has an inlet and an outlet. The inlet is in fluid communication with an exterior of the enclosure, and the outlet is in fluid communication with an interior of the enclosure. The labyrinth defines a tortuous path between the inlet and the outlet. In order to thermally isolate the enclosure, it can be surrounded by an air gap of at least 10 mm separating the enclosure from other components of the processing apparatus, to prevent damage to such other components. The thermal isolation can also be achieved by forming the enclosure from double walls with a 10 mm gap therebetween. The pyrophoric enclosure can have a separate exhaust duct and/or scrubber than those of a semiconductor processing reactor associated with the enclosure.

### CLAIM FOR PRIORITY

The present application claims priority to U.S. Provisional Application No. 60/835,140, filed Aug. 1, 2006.

### INCORPORATION BY REFERENCE

The present application incorporates by reference the entire disclosures of U.S. Patent Application Publication No. 2005/0000428A1 and U.S. Provisional Application No. 60/835,140.

### BACKGROUND OF THE INVENTION

1. Field of the Invention

The present application relates generally to semiconductor processing equipment and specifically to equipment that uses pyrophoric precursors.

2. Description of the Related Art

During semiconductor processing, various reactant gases are fed into a reaction chamber containing a semiconductor substrate or wafer, such as a silicon wafer. The injection of reactant gases causes the deposition of layers of materials onto the substrate, which layers form structures of very fine dimensions, such as integrated circuits. Chemical vapor deposition (CVD) involves the chemical reaction of two precursor gases over the substrate, wherein the layer growth depends on the bulk flow of the precursors and/or the temperature.

Atomic layer deposition (ALD) involves the alternating introduction of two complementary precursors into the reaction chamber. Typically, a first precursor will adsorb onto the substrate surface, but it cannot completely decompose without the second precursor. The first precursor adsorbs until it saturates the substrate surface; further growth cannot occur until the second precursor is introduced. Thus, the film thickness is controlled by the number of precursor injection cycles rather than the deposition time, as is the case for conventional CVD processes. Accordingly, ALD allows for extremely precise control of film thickness and uniformity. Some ALD precursor sources are provided in powder or liquid form. In these cases, the precursor source may need to be heated to produce sufficient amounts of vapor for the reaction process. ALD precursor sources are typically contained within specialized source vessels.

ALD processes can require the periodic use of precursor chemistries that are pyrophoric, i.e., which are flammable when in contact with air. Pyrophoric precursor sources can be in solid (e.g., powder), liquid, or gaseous forms. Solid and liquid precursor sources may need to be heated to produce sufficient amounts of vapor for the reaction process. One example of a pyrophoric precursor is trimethyl aluminum (TMA), which is normally in liquid form.

### SUMMARY OF THE INVENTION

In accordance with one embodiment, a semiconductor processing apparatus comprises an enclosure, a pyrophoric source vessel within the enclosure, and an air intake labyrinth extending away from the enclosure. The vessel is adapted to contain a pyrophoric material. The labyrinth has an inlet and an outlet. The inlet is in fluid communication with an exterior of the enclosure, and the outlet is in fluid communication with an interior of the enclosure. The labyrinth defines a tortuous path between the inlet and the outlet.

In accordance with another embodiment, a semiconductor processing apparatus comprises an enclosure and a pyrophoric source vessel within the enclosure. The enclosure is substantially surrounded by an air gap of at least 10 mm separating the enclosure from other components of the processing apparatus, with the exception of a structure for mounting or suspending the enclosure. The vessel is adapted to contain a pyrophoric material.

In accordance with another embodiment, a semiconductor processing apparatus comprises an enclosure defined by double walls separated by at least 10 mm, and a pyrophoric source vessel within the enclosure. The vessel is adapted to contain a pyrophoric material.

In accordance with another embodiment, a semiconductor processing apparatus comprises at least one reactor, a main exhaust extending from the reactor, a main scrubber connected downstream of the main exhaust, an enclosure, a pyrophoric source vessel within the enclosure, a pyrophoric exhaust duct extending from and in fluid communication with an interior of the enclosure, a pyrophoric precursor scrubber downstream of the pyrophoric exhaust duct, one or more additional precursor sources, and a gas delivery system. The pyrophoric source vessel is adapted to contain a pyrophoric material. The reactor is configured to contain a substrate, and the gas delivery system is configured to deliver vapors of said pyrophoric material and said one or more additional precursor sources to a substrate in the reactor.

In accordance with another embodiment, a method comprises providing an enclosure, a pyrophoric source vessel in the enclosure, an air intake labyrinth extending away from the enclosure, and an exhaust opening in the enclosure. The pyrophoric source vessel contains a pyrophoric material. The air intake labyrinth has an inlet and an outlet. The inlet is in fluid communication with an exterior of the enclosure, and the outlet is in fluid communication with an interior of the enclosure. The labyrinth defines a tortuous path between the inlet and the outlet. The method further comprises drawing air from the exterior of the enclosure through the air intake labyrinth, the enclosure, and the exhaust opening.

In accordance with another embodiment, a method of processing a semiconductor substrate comprises providing an enclosure substantially surrounded by an air gap of at least 10 mm separating the enclosure from other components of a semiconductor processing apparatus, with the exception of a structure for mounting or suspending the enclosure. The method further comprises providing a pyrophoric source vessel within the enclosure, and directing a carrier gas through the vessel and onward to a semiconductor substrate, the vessel containing a pyrophoric material.

In accordance with another embodiment, a method of processing a semiconductor substrate comprises providing an enclosure defined by double walls separated by at least 10 mm, providing a pyrophoric source vessel within the enclosure, and directing a carrier gas through the vessel and onward to a semiconductor substrate, the vessel containing a pyrophoric material.

In accordance with another embodiment, a method of processing a semiconductor substrate comprises placing a semiconductor substrate within a substrate processing reactor; providing a pyrophoric source vessel within an enclosure, the vessel containing a pyrophoric material; providing at least one additional precursor source vessel containing an additional precursor material; directing carrier gases through the pyrophoric source vessel and the at least one additional precursor source vessel to the substrate in the reactor, thereby delivering vapors of said pyrophoric material and said additional precursor material to the substrate; directing said vapors through a main exhaust extending from the reactor to a main scrubber downstream of the main exhaust; and drawing gas from within the enclosure through a pyrophoric exhaust duct to a pyrophoric precursor scrubber downstream of the pyrophoric exhaust duct.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the present invention herein disclosed. These and other embodiments of the present invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIG. 1 is a top perspective view of an embodiment of a frame assembly for an atomic layer deposition processing apparatus.

FIG. 2 is a top perspective view of an embodiment of a portion of the processing apparatus that may be housed within the frame assembly of FIG. 1.

FIG. 3 is a front perspective view of an embodiment of a pyrophoric precursor enclosure box of the processing apparatus of FIG. 2.

FIG. 3A is a schematic cross-sectional view of an alternative embodiment of a pyrophoric precursor enclosure box.

FIG. 4 is a schematic illustration of an embodiment that uses safety interlock switches to shut-off the processing system.

FIG. 5 is a front perspective view of the precursor enclosure box of FIG. 3, with the door removed.

FIG. 6 is a rear perspective view of the precursor enclosure box of FIG. 3.

FIG. 7 is a front perspective view of the precursor enclosure box of FIG. 3, with an internal precursor source vessel shown.

FIG. 8 is a front perspective view of an embodiment of an air intake labyrinth attachable to an air intake of the precursor enclosure box of FIG. 3.

FIG. 9 is a rear view of the air intake labyrinth of FIG. 8.

FIG. 10 is a cross-sectional view taken along line 10-10 of FIG. 9.

FIG. 10A is the same view as FIG. 10, illustrating a flow of air through the air intake labyrinth.

FIG. 11 is a schematic view of a pyrophoric precursor enclosure box with an associated smoke detector.

FIG. 12 is a perspective view of one embodiment of a pyrophoric safety enclosure box with an associated flame detector.

FIG. 13 is a perspective view of another embodiment of a pyrophoric safety enclosure box with an associated flame detector.

FIG. 14 is a schematic view of a pyrophoric safety enclosure box showing the relative positions of the flame detectors of the embodiments of FIGS. 12 and 13.

FIG. 15 is a perspective view of another embodiment of a pyrophoric safety enclosure box, with yet another location for mounting an associated flame detector.

FIG. 16 is a schematic view of an embodiment of a substrate processing system.

### DETAILED DESCRIPTION OF THE PREFERRED EMBODIMENT

One problem with ALD processing systems that use pyrophoric precursor sources is that the precursor can leak from its source vessel and catch on fire due to contact with oxygen. This can present a significant safety hazard to equipment handlers under certain conditions. For example, if a pyrophoric material such as trimethyl aluminum (TMA) leaks from its source vessel into an air-tight enclosure box of low oxygen concentration, the pyrophoric material may smolder. However, if the enclosure is opened by an operator, the sudden increase in oxygen can cause the pyrophoric material to explode in a flash fire. Accordingly, methods and equipment are needed to detect pyrophoric source leaks to prevent such events.

### Frame Assembly

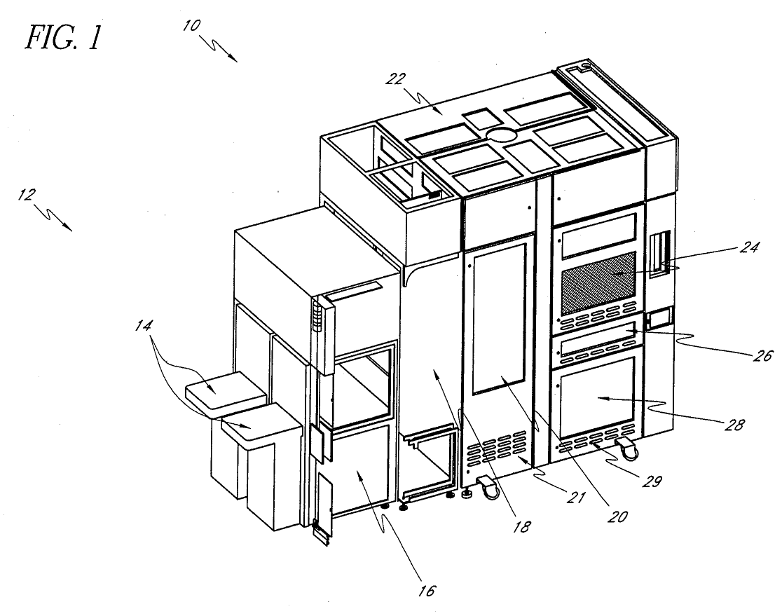

FIG. 1 is a top perspective view of one embodiment of a frame assembly 10 for an atomic layer deposition processing. Skilled artisans will appreciate that FIG. 1 is illustrative only, and certain details are omitted for ease of illustration. The processing apparatus includes a front-end interface 12 comprising substrate cassette load port platforms 14, a substrate transport chamber 16, and a load lock 18, all of which are well known in the art. The frame assembly 10 includes a compartment 20 that houses two substrate-processing reactors. As used herein, a “reactor” is a device that includes a reaction chamber in which substrates can be processed by a process reaction (e.g., CVD or ALD). A reactor is capable of receiving precursor gases and may include heaters for controlling the temperature inside the reaction chamber. While the illustrated frame assembly 10 houses two reactors, it will be understood that any suitable number of reactors can be housed for improved capability (e.g., throughput), with due consideration to the goal of maintaining a reasonable apparatus size. The reactor compartment 20 is accessed by a door 21.

A controls chassis 22 houses power components for the processing apparatus. A compartment 24 houses a gas panel from which a technician or operator can control gas valves, mass flow controllers, pressure transducers, and regulators for the processing apparatus. A compartment 26 houses a gas “lock out tag out” box, from which the operator can manually shut off certain mechanical valves for maintenance purposes. A compartment 28 houses a pneumatics panel from which the operator can control various pneumatic robotics (e.g., pedestals that raise and lower substrates). The compartment 28 also houses one or more precursor source enclosure boxes, as described in detail below. The compartment 28 is accessed by a door 29. Skilled artisans will understand that the various components described and shown in FIG. 1 can be arranged in a large variety of different configurations and assemblies, and that the present invention is not limited to the one illustrated.

### Processing Apparatus

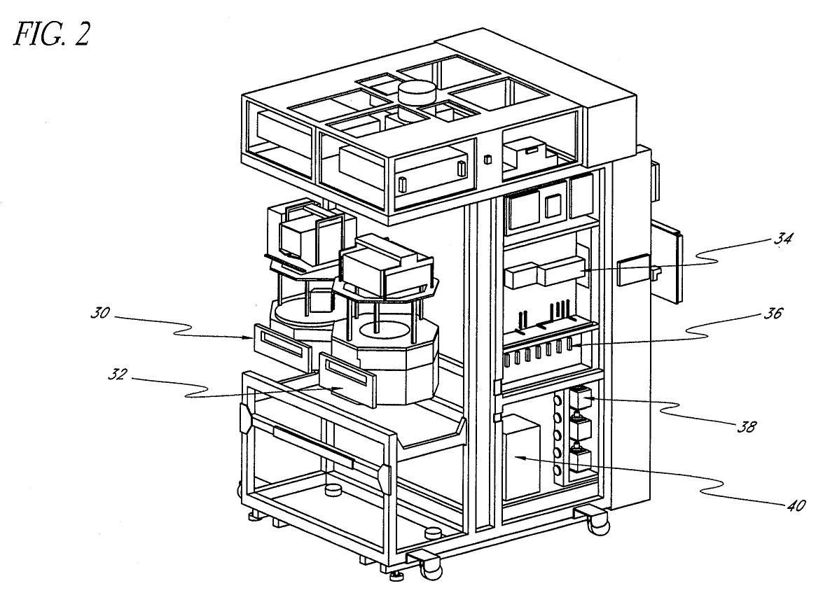

FIG. 2 is a top perspective view of one embodiment of a portion of a processing apparatus that may be housed within the frame assembly 10 of FIG. 1. Skilled artisans will appreciate that FIG. 2 is illustrative only, and certain details are omitted for ease of illustration. The illustrated apparatus includes two reactors 30 and 32. The reactors 30 and 32 are preferably different in nature. For example, one reactor may include a showerhead gas injector (as known in the art), which is preferred for certain types of reactions, while the other reactor may include a horizontal flow injector that is more appropriate for other reaction types. Also shown is a gas panel 34, gas lock out tag out box 36, and pneumatics panel 38, as described above.

With continued reference to FIG. 2, the processing apparatus includes one or more precursor source enclosure boxes 40. In one embodiment, the processing apparatus includes one enclosure box 40 for a pyrophoric precursor source and one enclosure box 40 for a non-pyrophoric precursor source. However, skilled artisans will understand that any number of enclosure boxes 40 can be provided, perhaps depending upon the specific types of reactions intended. Skilled artisans will also understand that any number of the enclosure boxes 40 can be for pyrophoric precursors.

### Pyrophoric Precursor Enclosure

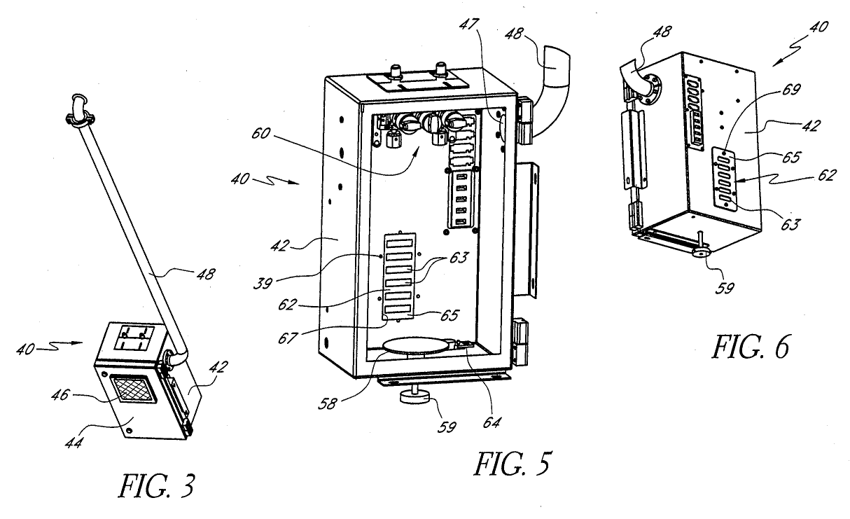

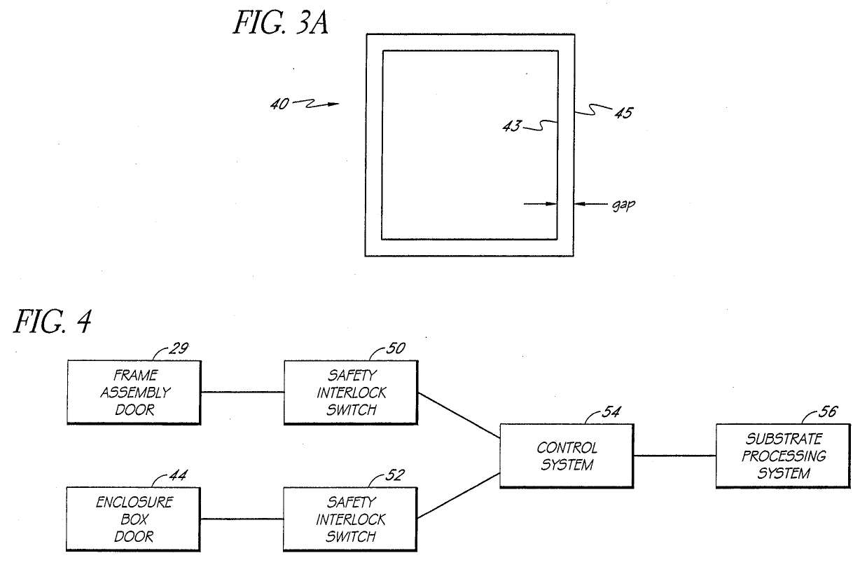

FIG. 3 is a front perspective view of one embodiment of a pyrophoric precursor enclosure box 40 of the processing apparatus of FIG. 2. The enclosure box 40 includes an enclosure body 42, a hinged door 44, a safety glass window 46, and an exhaust duct 48. The enclosure body 42 preferably comprises a relatively thick material that serves to thermally isolate the enclosure's interior from the exterior. For example, the enclosure body 42 and door 44 can comprise a fire retardant material, such as stainless steel (preferably at least 12 gauge stainless steel, welded). In the event that the pyrophoric precursor leaks and catches on fire inside the enclosure 40, the enclosure body 42 is preferably configured to prevent significant transmission of the heat to external components that could otherwise be damaged thereby. It is also preferred to provide an air jacket substantially surrounding the enclosure body 42, in order to further thermally isolate the enclosure box 40. For example, external components are preferably positioned no closer than a certain distance (e.g., 10 mm) from the body 42 and/or an exhaust duct 48 (described below), with the possible exception of structural apparatus for supporting, mounting, or suspending the body 42 and duct 48. Alternatively or additionally, the body 42 can comprise double walls with an air gap (e.g., at least 10 mm) therebetween. For example, FIG. 3A shows an enclosure box 40 defined by an inner wall 43 and an outer wall 45, with a gap therebetween. Referring again to FIG. 3, the door 44 preferably provides an air-tight seal when closed, such that air cannot enter or escape the enclosure box 40 through the interface between the door jamb and the door 44.

With reference to FIGS. 1 and 3, one or both of the doors 29 and 44 can be linked to a safety interlock switch that prevents system operation while the door is open. In this context, a safety interlock switch is a mechanical switch that is linked to the system electronics. The safety interlock switch is open or closed depending upon the position of a door associated with the switch. When the door is open, the switch preferably electrically disables at least a portion of the entire processing system, such that it is not possible to process substrates or flow precursor gases. In a preferred embodiment, separate safety interlock switches are provided for the external door 29 of the frame assembly 10, and for the internal door 44 of the enclosure box 40. Alternatively, only one of such doors can be configured with a safety interlock switch. The safety interlock switch may comprise, for example, a first electrical contact on an edge of the door and a second electrical contact on a door jamb, the two contacts positioned to electrically contact one another when the door is closed.

FIG. 4 schematically illustrates one embodiment that uses safety interlock switches. In this system, the external frame assembly door 29 (FIG. 1) is linked to a first safety interlock switch 50, and the internal enclosure box door 44 (FIG. 3) is linked to a second safety interlock switch 52. Box 56 represents the substrate processing subsystem, and may encompass one or more processing reactors. Box 54 represents an electronic control system that controls the operation of the substrate processing subsystem 56. Preferably, the control system 54 is linked to the safety interlock switches 50 and 52 and can detect when either of the switches is open (which means that one of the doors 29, 44 is open). The control system 54 is preferably configured to disable the substrate processing subsystem 56 when either one of the doors 29, 44 is open.

As an additional safety measure, a special mechanical tool or key may be required to open both the external door 29 of the frame assembly 10 (FIG. 1) and the door 44 of the enclosure box 40 (FIG. 3). In this embodiment, the doors may each have one or more special latches or locks that can only be opened by using the tool or key. In some embodiments, the tool or key is different for each door.

Referring again to FIG. 3, the enclosure door 44 preferably includes a safety glass window 46 that allows an operator to view the interior of the enclosure box 40 during processing. This allows the operator to visibly detect whether the precursor source is leaking and whether it has caught on fire.

The exhaust duct 48 extending from the enclosure box 40 is preferably formed of fire retardant material, such as stainless steel. In one embodiment, the exhaust duct 48 comprises a pipe about ½ inches in diameter. As explained in further detail below, air can be drawn from within the enclosure box 40 through the exhaust duct 48 to a dedicated scrubber, i.e., a scrubber different than that which receives exhaust gases from a main exhaust of the processing apparatus. As mentioned above, the processing apparatus can have any suitable number of pyrophoric precursor enclosure boxes. Preferably, each pyrophoric precursor enclosure box has an exhaust duct leading to a dedicated scrubber. In other words, as the number of separate pyrophoric precursors increases, so preferably increases the number of separate scrubbers.

FIG. 5 is a front perspective view of the precursor enclosure box 40, with the door 44 removed to show the interior of the enclosure body 42. The illustrated enclosure box includes a pedestal 58 for supporting a precursor source vessel, described below. Preferably, the vertical position of the pedestal 58 can be adjusted, such as by a lower height adjustment knob 59 (for example, with an associated leadscrew height adjustment assembly). A gas connection assembly 60 is preferably configured to connect to a gas inlet and outlet of the precursor source vessel. The gas connection assembly 60 is provided to inject a carrier gas through the precursor source vessel to obtain a precursor vapor that can be injected into a substrate reaction chamber for substrate processing (e.g., ALD).

A back wall of the illustrated enclosure body 42 includes an air intake 62. In use, as mentioned above, air is preferably drawn from within the enclosure box 40 through the exhaust duct 48. This can be achieved by using a vacuum or suction pump downstream of the inlet 47 of the exhaust duct 48. Thus, during processing, air is continuously drawn from the clean room through the air intake 62 to the exhaust duct 48. This flow of air advantageously helps to prevent fire within the enclosure box 40 (which may occur due to leakage of a pyrophoric precursor source) from escaping the enclosure box and possibly damaging nearby equipment or harming an operator. Preferably, air is drawn from the enclosure box 40 into the exhaust duct 48 at a rate sufficient to replace the internal air of the enclosure box 40 at least 3-4 times per minute.

FIG. 6 is a rear perspective view of the precursor enclosure box 40 of FIGS. 3 and 5, also showing the air intake 62. With reference to FIGS. 5 and 6, the illustrated air intake 62 includes a plurality of slits 63 formed in an intake plate 65 secured over a rectangular opening 67 in the enclosure body 42. The illustrated intake plate 65 includes holes 69 that align with holes 39 of the enclosure body 42 to facilitate attachment, such as by screws or nut and bolt combinations. While the illustrated air intake 62 includes a plurality of slits 63, skilled artisans will appreciate that any number, size, and shape of intake openings can be provided, giving due consideration to the goal of facilitating a desired range of flow through the air intake 62. In a preferred embodiment, the intake plate 65 is removed, such that the air intake 62 simply comprises the rectangular opening 67 over which the intake plate 65 was secured. In such an embodiment, the air intake labyrinth (described below) preferably attaches directly to the enclosure body 42 over the opening 67, for example by using the holes 39.

With continued reference to FIG. 5, a leak detector 64 is preferably provided at or near the bottom of the interior of the enclosure box 40. The leak detector 64 is typically only useful for detecting leakage of a liquid precursor source (as opposed to solid or gaseous sources) from the source vessel. A variety of different types of leak detectors are known and commercially available. In one embodiment, the leak detector 64 operatively communicates with a control system (e.g., the control system 54 of FIG. 4, or another electronic control system) for automatically shutting off the valves associated with the pyrophoric precursor source vessel 66 (described below). Thus, if the flammable precursor leaks from the vessel, the flow of gases (e.g., carrier gases) through the vessel is preferably stopped to prevent any exacerbation of a possible fire caused by the leak.

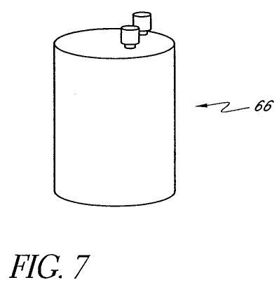

FIG. 7 is a front perspective view of an embodiment of a precursor source vessel 66 that can be supported on the pedestal 58 of the precursor enclosure box of FIGS. 3, 5, and 6. The source vessel 66 has a gas inlet and outlet connected to the gas connection assembly 60 of the enclosure box 40. The source vessel 66 can vary in size and shape, depending to some degree on the size and shape of the enclosure box 40. In one embodiment, the enclosure box 40 has a height of about 475 mm, and the precursor source vessel 66 has a height of about 238 mm and has an internal volume of 1000 cc. Preferably, the volume of the enclosure box 40 (after subtracting the volume of the vessel 66) is large enough to contain at least 125% of the maximum volume of the vessel 66. Thus, if the entire precursor source leaks out of the vessel 66, it will not fill the available volume of the enclosure box 40. Also, the volume of the vessel 66, the available volume of the enclosure box 40, and the vertical position of the openings of the air intake 62 are preferably such that the precursor source will not leak out of the air intake 62 in the event of a vessel leak.

Preferably, the enclosure box 40 does not contain any flammable materials or accelerants that would exacerbate a fire caused by a leak of pyrophoric material from the source vessel 66. Thus, the box 40 preferably does not contain any electronics, printed circuit boards, or other flammable materials. Also, it will be understood that gas lines may extend from the vessel 66 inside the enclosure box 40, for the purpose of flowing gases (e.g., carrier gases) through the vessel. Preferably, the portions of such gas lines extending from the vessel 66 inside the enclosure box 40 are not flammable. For example, the gas lines can be metal pipes, and are preferably not plastic (such as PVC). Valves (e.g., pneumatically controlled valves) associated with such gas lines are preferably positioned outside of the enclosure box 40.

With reference to FIGS. 5 and 6, when using the enclosure box 40 it is desirable that air flows in one general direction through it—from the air intake 62 to the exhaust duct 48. As mentioned above, air is preferably drawn from within the box 40 through the exhaust duct 48, for example by using a vacuum or suction pump downstream of the inlet 47 of the exhaust duct 48. However, if for some reason air begins flowing in the opposite direction, there is a risk that leaked pyrophoric material or fire could breach the enclosure box 40 through the air intake 62, possibly injuring someone and/or damaging equipment. Thus, during use, it is helpful to know the direction of airflow through the box 40. Accordingly, an enclosure exhaust draw monitor can be provided to monitor the direction of airflow through the pyrophoric enclosure box 40 (other than the flow through the gas lines extending to/from the pyrophoric vessel 66). A variety of different types of airflow monitors can be used. One type of exhaust draw monitor is a pressure sensor that measures the pressure differential between the interior and exterior of the box 40 (it being understood that “exterior” does not encompass the interior of the exhaust duct 48, but rather the region outside of the air intake 62). If the exterior pressure is greater than the exterior pressure, then it can be presumed that air is flowing in the desired direction, toward the exhaust duct 48. However, if the exterior pressure is less than the interior pressure (as may occur, for example, if the duct 48 becomes blocked), then air is probably flowing in the opposite direction. The exhaust draw monitor is preferably operatively connected to a control system (e.g., the control system 54 of FIG. 4 or another electronic control system) for automatically alerting users of the potential danger caused by air flowing out of the air intake 62, and/or for automatically shutting off the valves associated with the pyrophoric precursor source vessel 66.

### Air Intake Labyrinth

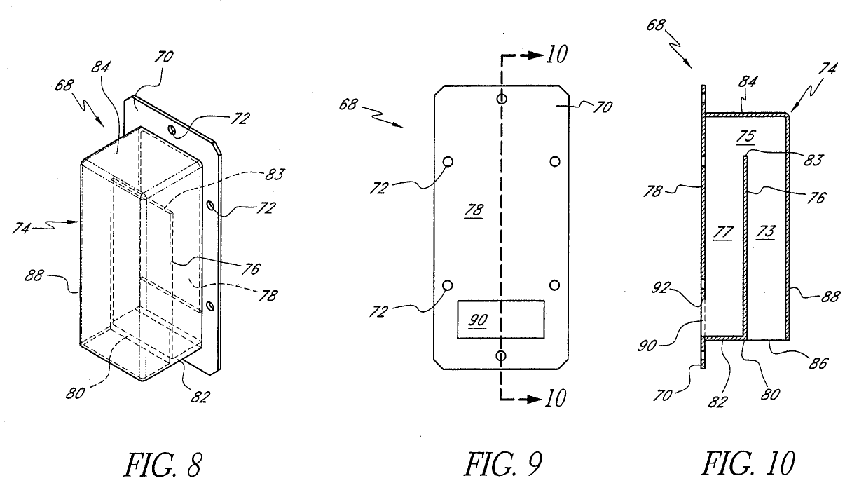

FIGS. 8-10 show an embodiment of an air intake labyrinth 68 that can be attached to the air intake 62 (FIGS. 5-7) of the enclosure box 40. The air intake labyrinth 68 causes air to flow along a somewhat tortuous path before it enters the enclosure box 40 through the air intake 62. If a pyrophoric precursor source material leaks from the vessel 66 (FIG. 7) and catches on fire, the air intake labyrinth 68 substantially prevents the escape of flames and possibly even smoke from the enclosure box 40. Without the air intake labyrinth 68, such flames could possibly damage other equipment or harm an operator. Also, smoke that escapes from the enclosure box 40 can introduce unwanted contamination into the clean room environment.

The illustrated air intake labyrinth 68 includes an attachment flange 70 with screw or bolt holes 72 for attaching the intake labyrinth 68 to corresponding holes of the enclosure box 40. The intake labyrinth 68 also includes a body 74, a divider wall 76, and a base wall 78. The illustrated body 74 is substantially rectangular, but could have other shapes. The divider wall 76 divides the body 74 into two vertical pathways. The illustrated divider wall 76 extends from a lower edge 80 to an upper edge 83. The lower edge 80 is joined with a bottom wall 82 of the body 74, and the upper edge 83 terminates at a distance from an upper wall 84 of the body 74. An inlet 86 is defined at the lower edge of the body 74 between an outer wall 88 and the divider wall 76. An outlet 90 is defined at the lower edge of the body 74 between the bottom wall 82 and a lower edge 92 of the base wall 78.

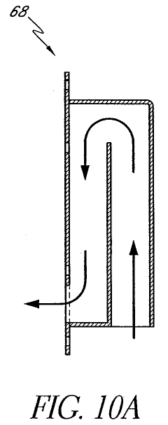

With reference to FIG. 10, the illustrated air intake labyrinth 68 defines a tortuous path comprising a first conduit 73 extending from the inlet 86 to a conduit junction 75, and a second conduit 77 extending from the conduit junction 75 to the outlet 90. The divider wall 76 extends from the inlet 86 to the conduit junction 75 and fluidly separates the first and second conduits except at the conduit junction. FIG. 10A shows the flow of air through the air intake labyrinth 68 during normal processing. As mentioned, the air flows along a tortuous path through the labyrinth 68, the air intake 62, and into the enclosure box 40.

Skilled artisans will understand that additional divider walls 76 can be provided to form an increasingly tortuous air intake path, giving due consideration to the goal of keeping the air intake labyrinth 68 at a reasonable size. Preferably, air flowing through the tortuous path flows through one or more turns of between 60°-180°, more preferably between 90°-180°, and even more preferably between 120°-180°, it being understood that a 180° turn causes the air to completely reverse its direction. Preferably, the cross-sectional area of the flow path through the air intake labyrinth 68 is at least 700 mm. In one embodiment, it is about 987 mm².

While the illustrated embodiment includes an air intake labyrinth 68 that is separately formed from and attached to the enclosure box 40, skilled artisans will understand that the labyrinth 68 and enclosure box 40 can be formed integrally.

### Smoke Detector

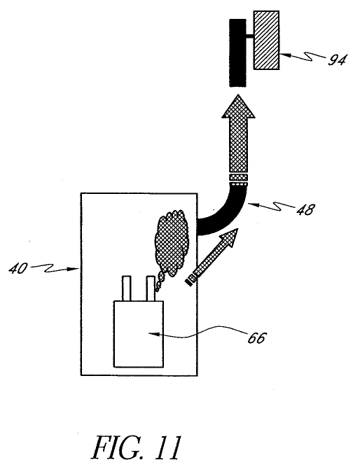

In a preferred embodiment, a smoke detector is provided to detect smoke inside the enclosure box 40. As explained above, smoke will be present if the precursor source material leaks from the vessel 66 and catches on fire. FIG. 11 is a schematic view of a pyrophoric precursor enclosure box 40 with an associated smoke detector 94. The smoke detector 94 can be positioned anywhere within the enclosure box 40, but is preferably located at a position at which it can detect smoke in the exhaust duct 48. In one embodiment, the smoke detector 94 is positioned at least partially or completely within the exhaust duct. During processing, air is drawn from the enclosure box 40 into the exhaust duct 48. Thus, placing the smoke detector 94 anywhere other than at least partially within the exhaust duct 48 or near the inlet 47 of the exhaust duct 48 might entail a risk that the smoke detector 94 would not detect the smoke. The smoke detector is preferably of a type that samples and analyzes particles in the air. Suitable smoke detectors 94 are known and commercially available.

As mentioned above, the processing apparatus can have any suitable number of pyrophoric precursor enclosure boxes. Preferably, each pyrophoric precursor enclosure box is equipped with at least one smoke detector, preferably located such that it can detect smoke within an exhaust duct extending from the enclosure box. In some embodiments, an additional smoke detector is also provided and located such that it can detect smoke within the main exhaust of the processing apparatus. The main exhaust is the exhaust duct for the process byproducts (i.e., downstream of the reactors).

As described above with respect to the leak detector 64 (FIG. 5), the smoke detector(s) 94 can operatively communicate with a control system (e.g., the control system 54 of FIG. 4 or another electronic control system) for automatically alerting users of the presence of smoke and/or shutting off the valves associated with the pyrophoric precursor source vessel 66.

### Flame Detector

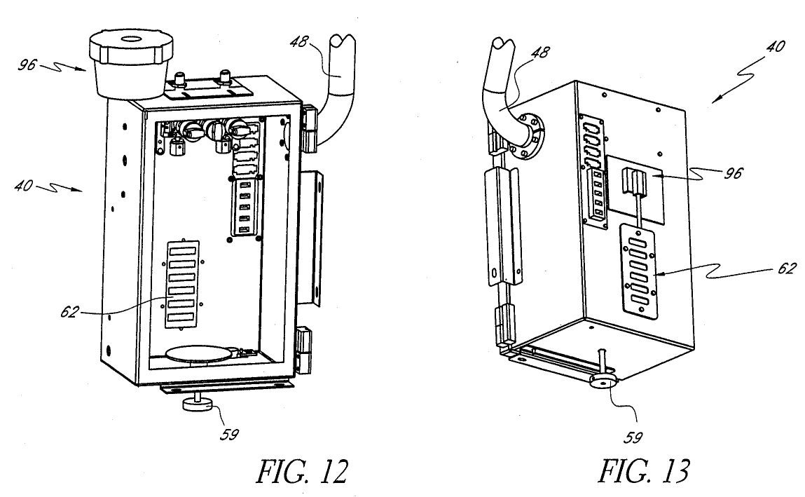

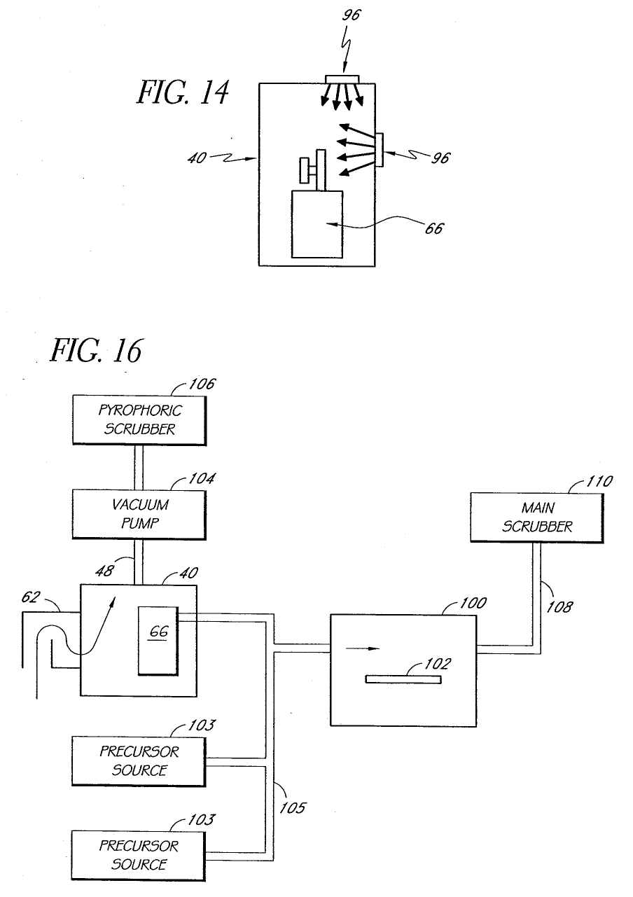

In a preferred embodiment, at least one flame detector is provided to detect the presence of flames within the enclosure box 40. FIG. 12 is a perspective view of a pyrophoric safety enclosure box 40 with an associated flame detector 96. The illustrated flame detector 96 preferably comprises an optical sensor that works within a specific spectral range (e.g., narrow band) to record electromagnetic radiation radiated from a fire within the enclosure box 40. For example, the flame detector 96 may comprise an ultraviolet (UV) infrared (IR) sensor. Suitable flame detectors are known and commercially available. In the illustrated embodiment, the flame detector 96 is positioned on an upper outer surface of the enclosure box 40, near a corner of the box 40. The flame detector 96 could be positioned somewhat closer to a vertical centerline of the box 40. In an alternative embodiment, shown in FIG. 13, the flame detector 96 is positioned on an outer surface of a sidewall of the enclosure box 40. FIG. 14 is a schematic view showing the relative positions of the flame detectors of the embodiments of FIGS. 12 and 13. In selecting the position of the flame detector 96, due consideration is preferably given to maximizing its visibility or field of view of the enclosure box interior. Preferably, the flame detector 96 is positioned to view all of the fluid (“fluid” being understood to comprise either a gas or liquid) connections within the enclosure box 40. Additional flame detectors can be provided to view all of such connections.

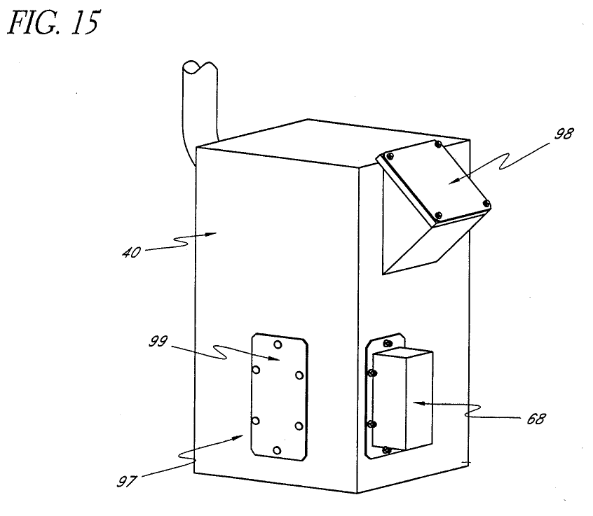

FIG. 15 is a perspective view of another embodiment of a pyrophoric safety enclosure box 40, with yet another location 98 for mounting an associated flame detector 96. The mounting surface 98 is angled to optimize the viewing angle of a flame detector 96 attached thereto. In FIG. 15, the air intake labyrinth 68 is shown attached to the enclosure box 40.

As mentioned above, the processing apparatus can have any suitable number of pyrophoric precursor enclosure boxes. Preferably, each pyrophoric precursor enclosure box is equipped with at least one flame detector. As described above with respect to the leak detector 64 (FIG. 5), the flame detector(s) 96 can operatively communicate with a control system (e.g., the control system 54 of FIG. 4 or another electronic control system) for automatically alerting users of the presence of fire and/or shutting off the valves associated with the pyrophoric precursor source vessel 66.

In some processes, it may be desirable to reduce the vapor pressure of the precursor gas. This can be accomplished by cooling the interior of the enclosure box 40 with a heat exchanger. FIG. 15 shows an optional cover plate 99 that covers an additional optional opening 97 in the body 42 of the enclosure box 40. The opening 97 and cover plate 97 can be provided to facilitate the use of a cooling apparatus comprising an air-to-air heat exchanger, such as a Peltier cooler. In use, the cover plate 99 is removed, exposing the opening 97. Then, a suitable heat exchanger is attached to the enclosure box at the opening 97. The heat exchanger is used to cool the interior of the enclosure box 40, thereby reducing the vapor pressure of the precursor delivered to the reactor(s). The embodiment of FIG. 15 can be used for both pyrophoric and non-pyrophoric precursors. When it is not necessary to use the heat exchanger, the heat exchanger can be disconnected from the enclosure box 40, and the cover plate 99 can be re-attached.

Some in the industry have proposed purging pyrophoric precursor enclosures with another gas (e.g., an inert gas such as N₂) during use of the pyrophoric precursor, in order to reduce the oxygen concentration in the enclosure (and thusly reduce the risk of a fire). This approach is not preferred for the present embodiments. A reduction in the oxygen concentration could prevent a detectable fire from occurring in the event of a leak of the pyrophoric material. For example, TMA might just smolder lightly. If the fire is not detected, the operator may not become aware of the leak and may open the door 44 of the enclosure box 40. The sudden increase in oxygen could result in a flash fire and harm to the operator and surrounding equipment.

### Dedicated Exhaust and Scrubber

FIG. 16 is a schematic of one embodiment of a substrate processing system using a pyrophoric precursor enclosure box 40 and source vessel 66. The system includes at least one substrate processing reactor or reaction chamber 100 for processing one or more substrates 102. The illustrated reactor 100 is a horizontal gas flow reactor for vapor deposition of gases onto a single substrate 102. However, skilled artisans will recognize that a variety of different reaction chambers can be used, such as chambers employing showerhead injectors, chambers for multiple substrates, and/or chambers designed for atomic layer deposition, chemical vapor deposition, etc. Although not shown, a susceptor can be provided for supporting the substrate 102 in the reaction chamber 100.

The system includes the pyrophoric precursor enclosure box 40 and a pyrophoric precursor source vessel 66 within the enclosure box 40, the vessel 66 containing a pyrophoric material. It will be appreciated that additional pyrophoric precursors can also be provided. An air intake labyrinth 62 is also shown attached to the enclosure box 40, preferably as described above. An exhaust 48 extends from the enclosure box 40 to a vacuum source 104, such as a vacuum pump or suction pump. A dedicated pyrophoric precursor scrubber 106 is provided in connection with the vacuum source 104.

One or more additional precursor sources 103 are also provided. A gas delivery system 105, illustrated as a plurality of interconnected pipes or tubes, is configured to deliver vapors of the pyrophoric material from the vessel 66 and vapors of the precursor sources 103 into the reaction chamber 100, for processing of the substrate 102. Although not shown, the gas delivery system 105 may also include a plurality of valves and a control system for controlling the flow of the vapors. A main exhaust 108 extends from the reaction chamber 100 to a main scrubber 110. The main exhaust directs process gases and reaction byproducts to the main scrubber 110.

Advantageously, unreacted pyrophoric material/vapors that may leak from the vessel 66 are drawn by the vacuum source 104 to the dedicated scrubber 106. Such materials/vapors do not flow to the main scrubber. The dedicated pyrophoric precursor scrubber 106 can be specially suited for the particular pyrophoric material.

Although the invention has been disclosed in the context of certain embodiments and examples, it will be understood by those skilled in the art that the invention extends beyond the specifically disclosed embodiments to other alternative embodiments and/or uses and obvious modifications and equivalents thereof. Accordingly, the invention is not intended to be limited by the specific disclosures of preferred embodiments herein.

What is claimed is:

1. A semiconductor processing apparatus, comprising:
an enclosure;
a pyrophoric source vessel within the enclosure, the vessel adapted to contain a pyrophoric material; and
an air intake labyrinth extending away from the enclosure, the labyrinth having an inlet and an outlet, the inlet being in fluid communication with an exterior of the enclosure, the outlet being in fluid communication with an interior of the enclosure, the labyrinth defining a tortuous path between the inlet and the outlet.

2. The apparatus of claim 1, wherein air flowing through the tortuous path flows through one or more turns of between 60°-180°.

3. The apparatus of claim 1, further comprising an exhaust duct extending from and in fluid communication with the interior of the enclosure.

4. The apparatus of claim 3, further comprising a vacuum source configured to draw air through the air intake labyrinth, the enclosure, and the exhaust duct.

5. The apparatus of claim 3, further comprising a smoke detector positioned to detect smoke within the exhaust duct.

6. The apparatus of claim 5, wherein the smoke detector is positioned at least partly within the exhaust duct.

7. The apparatus of claim 3, further comprising:
at least one reactor configured to contain a substrate;
one or more additional precursor sources;
a gas delivery system configured to deliver vapors of said pyrophoric material and said one or more additional precursor sources to a substrate in the reactor;
a main exhaust extending from the reactor;
a main scrubber connected downstream of the main exhaust; and
a pyrophoric precursor scrubber downstream of the exhaust duct extending from the interior of the enclosure.

8. The apparatus of claim 1, wherein the air intake labyrinth is formed separately and attached to the enclosure.

9. The apparatus of claim 1, further comprising a leak detector in the enclosure, the leak detector configured to detect leakage of a pyrophoric liquid from the vessel.

10. The apparatus of claim 1, further comprising a flame detector configured to detect fire within the enclosure.

11. The apparatus of claim 10, wherein the flame detector comprises a UV/IR sensor.

12. The apparatus of claim 1, further comprising a smoke detector configured to detect smoke within the enclosure.

13. The apparatus of claim 1, wherein the air intake labyrinth includes:
a first conduit extending from the inlet to a conduit junction;
a second conduit extending from the conduit junction to the outlet; and
a divider wall extending from the inlet to the conduit junction, the divider wall fluidly separating the first and second conduits except at the conduit junction.

14. The apparatus of claim 1, wherein the enclosure has an available volume outside of the source vessel of at least 125% of a volume of the source vessel.

15. The apparatus of claim 1, wherein the enclosure is substantially surrounded by an air gap of at least 10 mm separating the enclosure from other components of the processing apparatus.

16. The apparatus of claim 1, wherein the enclosure is defined by double walls separated by at least 10 mm.

17. The apparatus of claim 1, wherein the enclosure includes a door with a safety interlock switch configured to disable operation of the processing apparatus when the door is open.

18. The apparatus of claim 17, further comprising:
a frame assembly supporting the enclosure and other components of the apparatus, the frame assembly having a door providing access to the enclosure; and
a second safety interlock configured to disable operation of the processing apparatus when the door of the frame assembly is open.

19. A semiconductor processing apparatus, comprising:
an enclosure substantially surrounded by an air gap of at least 10 mm separating the enclosure from other components of the processing apparatus, with the exception of a structure for mounting or suspending the enclosure; and
a pyrophoric source vessel within the enclosure, the vessel adapted to contain a pyrophoric material.

20. A semiconductor processing apparatus, comprising:
an enclosure defined by double walls separated by at least 10 mm; and
a pyrophoric source vessel within the enclosure, the vessel adapted to contain a pyrophoric material.

21. A semiconductor processing apparatus, comprising:
at least one reactor configured to contain a substrate;
a main exhaust extending from the reactor;
a main scrubber connected downstream of the main exhaust;
an enclosure;
a pyrophoric source vessel within the enclosure, the vessel adapted to contain a pyrophoric material;
a pyrophoric exhaust duct extending from and in fluid communication with an interior of the enclosure;
a pyrophoric precursor scrubber downstream of the pyrophoric exhaust duct;
one or more additional precursor sources; and
a gas delivery system configured to deliver vapors of said pyrophoric material and said one or more additional precursor sources to a substrate in the reactor.

22. A method comprising:
providing an enclosure;
providing a pyrophoric source vessel within the enclosure, the vessel containing a pyrophoric material;
providing an air intake labyrinth extending away from the enclosure, the labyrinth having an inlet and an outlet, the inlet being in fluid communication with an exterior of the enclosure, the outlet being in fluid communication with an interior of the enclosure, the labyrinth defining a tortuous path between the inlet and the outlet;
providing an exhaust opening in the enclosure; and
drawing air from the exterior of the enclosure through the air intake labyrinth, the enclosure, and the exhaust opening.

23. A method of processing a semiconductor substrate, comprising:
providing an enclosure substantially surrounded by an air gap of at least 10 mm separating the enclosure from other components of a semiconductor processing apparatus, with the exception of a structure for mounting or suspending the enclosure;
providing a pyrophoric source vessel within the enclosure, the vessel containing a pyrophoric material; and
directing a carrier gas through the vessel and onward to a semiconductor substrate.

24. A method of processing a semiconductor substrate, comprising:
providing an enclosure defined by double walls separated by at least 10 mm;
providing a pyrophoric source vessel within the enclosure, the vessel containing a pyrophoric material; and
directing a carrier gas through the vessel and onward to a semiconductor substrate.

25. A method of processing a semiconductor substrate, comprising:
placing a semiconductor substrate within a substrate processing reactor;
providing a pyrophoric source vessel within an enclosure, the vessel containing a pyrophoric material;
providing at least one additional precursor source vessel containing an additional precursor material;
directing carrier gases through the pyrophoric source vessel and the at least one additional precursor source vessel to the substrate in the reactor, thereby delivering vapors of said pyrophoric material and said additional precursor material to the substrate;
directing said vapors through a main exhaust extending from the reactor to a main scrubber downstream of the main exhaust; and
drawing gas from within the enclosure through a pyrophoric exhaust duct to a pyrophoric precursor scrubber downstream of the pyrophoric exhaust duct.
